(19) United States
(12) Patent Application Publication
(10) Pub. No.: US 2021/0301418 A1
(43) Pub. Date: Sep. 30, 2021

(54) SIC CRYSTAL GROWTH DEVICE AND METHOD

(71) Applicant: Hunan Sanan Semiconductor Co., Ltd., Hunan (CN)

(72) Inventors: SHUJUN DENG, Hunan (CN); JIE ZHANG, Hunan (CN); LIANG WANG, Hunan (CN); FEN FU, Hunan (CN)

(21) Appl. No.: 17/212,726

(22) Filed: Mar. 25, 2021

(30) Foreign Application Priority Data
Mar. 31, 2020 (CN) 202010240314.4

(51) Int. Cl. C30B 23/06; C30B 29/36

(52) U.S. Cl. CPC C30B 23/066; C30B 29/36

(57) ABSTRACT

A SiC crystal growth device and method has a pie crucible and a heating mechanism. The pie crucible comprises a hollow inner cavity, and the center of the inner cavity is provided with a SiC crystal rod. The two ends of the SiC crystal rod are respectively abutting against the upper end face and the lower end face of the inner cavity. A SiC raw material is arranged in the circumferential direction of the inner cavity, and a gap exists between the SiC raw material and the SiC crystal rod. The heating mechanism is arranged outside the pie crucible, and is used for establishing a temperature field with gradually decreasing temperature from SiC raw materials to SiC crystal rods.

### CROSS-REFERENCE TO RELATED APPLICATIONS

This application claims priority to Chinese Utility Patent Application No. 202010240314.4 entitled “SIC CRYSTAL GROWTH DEVICE AND METHOD” filed before China's National Intellectual Property Administration on Mar. 31, 2020, the entire contents of each of which are incorporated herein by reference.

### STATEMENT RE: FEDERALLY SPONSORED RESEARCH/DEVELOPMENT

Not Applicable

### BACKGROUND

### 1. Technical Field

The present disclosure relates to the technical field of SiC crystal preparation, in particular to a SiC crystal growth device and method.

### 2. Related Art

Silicon carbide single crystal material is the representative of the third generation wide band gap semiconductor material, which has the characteristics of wide band gap, high thermal conductivity, high breakdown electric field and high radiation resistance. At present, physical vapor deposition (PVT) is the main growth method of silicon carbide single crystal, which has been proved to be the most mature method for growing SiC crystal. SiC powder is heated to 2300° C., and sublimated and crystallized into massive crystals under inert gas atmosphere such as argon. In the growth process, it is necessary to establish a suitable temperature field, so that the vapor components Si, Si2C, SiC2 can grow on the seed crystal stably.

Commercially available SiC crystals range in size from 2 inches, 3 inches, 4 inches, 6 inches, and even 8 inches or more. The existing method of expanding crystal diameter is to adjust the crystal growth interface to a convex interface as much as possible in the process of growing SiC crystal by PVT method. During the crystal growth process, the diameter is continuously expanded. Generally, the diameter can be expanded by 3-5 mm at most in one heat. After slicing, the crystal is placed in a larger crucible again for growth, and the final diameter expansion can be realized by repeating for many times. However, it usually takes dozens of times for SiC crystals to multiply from 2 inches to 8 inches, and it is easy for the crystals to collapse and crack during processing, and the yield is low.

### SUMMARY

The purpose of the present disclosure is to provide a SiC crystal production device and method, so as to alleviate the technical problems that when the existing crystal diameter expanding method expands from small-sized crystals to large-sized crystals. Such limitations include the crucible needing to be repeatedly replaced for diameter expansion, the yields being low, and the diameter expanding time being long.

The SiC crystal growth device provided by the various embodiments of the present disclosure comprises a pie crucible and a heating mechanism.

The pie crucible may comprise a hollow inner cavity. A SiC crystal rod may be arranged in the center of the inner cavity, and two ends of the SiC crystal rod may respectively be abutted with the upper end face and the lower end face of the inner cavity. A SiC raw material may be arranged in the circumferential direction of the inner cavity, and a gap may be formed between the SiC raw material and the SiC crystal rod.

The heating mechanism may be arranged outside the pie-shaped crucible and used for constructing a temperature field with gradually decreasing temperature from the SiC raw material to the SiC crystal rod, so that the sublimated gas of the SiC raw material can diffuse towards the SiC crystal rod and be deposited on the side wall of the SiC crystal rod.

Further, the heating mechanism may comprise a heating body and an insulating layer.

The thermal insulation layer may cover the circumference, top and bottom of the pie crucible. Additionally, the heating body may be arranged outside the insulation layer.

Further, the heating body may be an induction coil.

Furthermore, the insulation layer may be a graphite soft felt insulation layer.

The SiC crystal growth method provided by the embodiments of the present disclosure may comprise the following steps:

Setting SiC crystal rod at the center of the inner cavity of the pie crucible;

Setting SiC raw materials in the circumferential direction of the inner cavity with a gap between the SiC raw materials and the SiC crystal rods;

Establishing a temperature field with gradually decreasing temperature from the SiC raw material to the SiC crystal rod.

Further, the step of constructing a temperature field with gradually decreasing temperature between the SiC raw material and the SiC raw material may comprise:

Placing the pie crucible in an insulating layer;

The temperature field may be constructed by adopting an induction coil or a heating resistor.

Furthermore, the heating temperature of the SiC crystal rod is 2000-2300 deg c;

Heating temperature of SiC raw material is 2200-2600 deg. c.

Furthermore, the heating temperature of the SiC crystal rod is 2200 deg c;

Heating temperature of SiC raw material is 2300° C.

Furthermore, the crystal form of the SiC crystal rod is 4H or 6H crystal form.

Further, the SiC raw material is an annular SiC block or a plurality of stacked SiC blocks.

The SiC crystal growth device provided by the invention may comprise a pie crucible and a heating mechanism. The pie crucible may comprise a hollow inner cavity, a SiC crystal rod is arranged in the center of the inner cavity, and two ends of the SiC crystal rod are respectively abutted with the upper end face and the lower end face of the inner cavity. A SiC raw material may be arranged in the circumferential direction of the inner cavity, and a gap may be formed between the SiC raw material and the SiC crystal rod. The heating mechanism may be arranged outside the pie crucible and used for constructing a temperature field with gradually decreasing temperature from the SiC raw material to the SiC crystal rod, so that the sublimated gas of the SiC raw material can diffuse towards the SiC crystal rod and deposit on the side wall of the SiC crystal rod, SiC gas heated and sublimated from SiC raw materials can be transported to SiC crystal rods and deposited, which makes the SiC crystal rods grow bigger in the lateral direction, thus growing small-sized SiC crystal rods into large-sized crystals without changing crucibles for many times, with high yield, short crystal diameter expanding time and high production efficiency.

The SiC crystal growth method provided by the present disclosure comprises the following steps: arranging a SiC crystal rod at the central position of an inner cavity of a pie-shaped crucible; Setting SiC raw materials in the circumferential direction of the inner cavity with a gap between the SiC raw materials and the SiC crystal rods; Establishing a temperature field with gradually decreasing temperature from the SiC raw material to the SiC crystal rod. According to the SiC crystal growth method provided by the present disclosure, the lateral direction (radial direction) of the whole SiC crystal rod is taken as a growth surface, and the diameter of the SiC crystal rod is rapidly expanded by establishing a suitable growth environment, so that the time is short and the yield is high.

### BRIEF DESCRIPTION OF THE DRAWINGS

In order to explain the specific embodiment of the present disclosure or the technical scheme in the prior art more clearly, the drawings used in the description of the specific embodiment or the prior art will be briefly introduced below. The drawings in the following description are some embodiments of the present invention, and other embodiments may be derived therefrom by those having ordinary skill in the art.

FIG. 1 is a schematic structural diagram of a SiC crystal growth device provided by an embodiment of the present disclosure;

FIG. 2 is a schematic diagram of the arrangement of SiC crystal rods and SiC raw materials in a pie crucible of the SiC crystal growth device provided by an embodiment of the present disclosure;

FIG. 3 is a schematic diagram of the completion of the crystal diameter expansion of the SiC crystal growth device provided by the embodiment of the present disclosure;

FIG. 4 is a flowchart of a SiC crystal growth method provided by an embodiment of the present disclosure.

Icon: 100—pie crucible; 110—inner cavity; 210—insulation layer; 220—induction coil; 300—SiC crystal rod; 400—SiC raw material.

### DETAILED DESCRIPTION

In the following, the technical scheme of the present invention will be described with examples. The described examples are but a few of the embodiments of the present disclosure, not all of them. Based on the embodiments of the present disclosure, all other embodiments within the purview of those having ordinary skill in the art are deemed to be within the scope of the present disclosure.

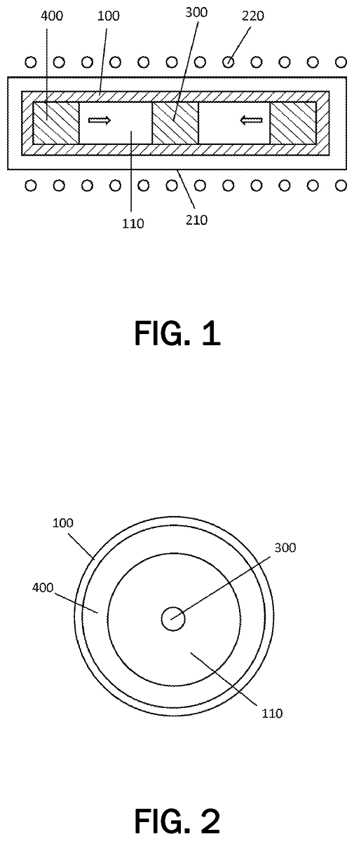

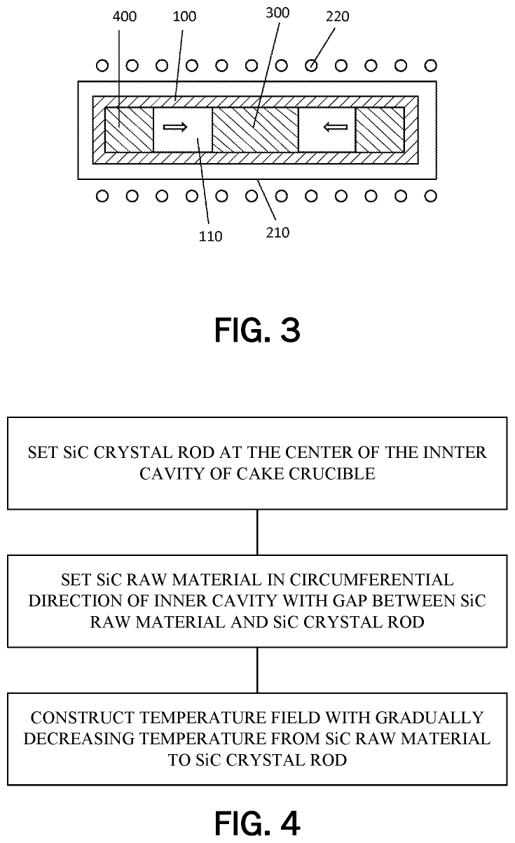

As shown in FIGS. 1-3, the SiC crystal growth device provided by the present disclosure includes a pie crucible 100 and a heating mechanism.

The pie crucible 100 comprises a hollow inner cavity 110, the center of the inner cavity 110 is provided with a SiC crystal rod 300, and both ends of the SiC crystal rod 300 are respectively abutted against the upper end face and the lower end face of the inner cavity 110; A SiC raw material 400 is arranged in the circumferential direction of the inner cavity 110, and a gap exists between the SiC raw material 400 and the SiC crystal rod 300.

The SiC raw material 400 is placed in the annular region with the SiC crystal rod 300 as the center in the circumferential direction of the inner cavity 110. the SiC raw material 400 may be a monolithic polycrystalline SiC or a plurality of stacked SiC blocks.

The heating mechanism is arranged outside the pie crucible 100, and is used for constructing a temperature field with gradually decreasing temperature from the SiC raw material 400 to the SiC crystal rod 300, so that the sublimated gas of the SiC raw material 400 can diffuse towards the SiC crystal rod 300 and be deposited on the side wall of the SiC crystal rod 300.

In this embodiment, the SiC crystal rod 300 can be a SiC crystal block with a larger size or a crystal block with a smaller diameter.

A temperature field with gradually decreasing temperature from SiC raw material 400 to SiC crystal rod 300 is constructed by using a heating mechanism arranged in the circumferential direction of pie crucible 100. SiC gas heated and sublimated by SiC raw material 400 can be transmitted to SiC crystal rod 300 and deposited, so that SiC crystal rod 300 grows larger in the lateral direction, thus growing small-sized SiC crystal rod 300 into large-sized crystal, without changing crucible diameter for many times, with high yield, short crystal diameter expanding time and high production efficiency.

The pie crucible 100 can be made of high temperature resistant materials such as graphite and Ta.

Large-diameter wafers can be obtained by slicing SiC crystals after expanding growth, which avoids the conventional method of expanding growth that silicon carbide powder begins to sublimate into silicon carbide gas, which is transported from a high temperature region to a seed wafer at a lower temperature region along the temperature gradient to deposit crystals, gradually expand the diameter during the growth of Si or C surface of the crystal, slice after expanding to a certain diameter, and iteratively expand the diameter of a larger crucible again, with long expanding time and large stress of the expanded crystal. It is easy to crack and crack during processing. Therefore, the yield is not high.

Further, the heating mechanism includes a heating body and an insulating layer 210.

The insulation layer 210 covers the circumference, top and bottom of the pie crucible 100. The heating body is disposed outside the insulation layer 210.

Further, the heating body is an induction coil 220.

Specifically, the induction coils 220 can be respectively arranged on the upper end face and the lower end face of the pie-shaped crucible 100, and are composed of a plurality of concentric ring-shaped induction coils from the center of the pie-shaped crucible 100 to the center direction. By setting different power parameters of the ring-shaped induction coils, the temperature field from the SiC raw material 400 to the SiC crystal rod 300 is gradually decreased.

Further, the insulation layer 210 is a graphite felt insulation layer.

As shown in FIG. 4, the SiC crystal growth method provided by the present disclosure depends on the SiC crystal growth device, and specifically includes the following steps:

Setting SiC crystal rod 300 at the center of inner cavity 110 of pie crucible 100; Setting SiC raw material 400 in the circumferential direction of inner cavity 110 with a gap between SiC raw material 400 and SiC crystal rod 300; A temperature field with gradually decreasing temperature from SiC raw material 400 to SiC crystal rod 300 is constructed.

Further, the step of constructing the temperature field with gradually decreasing temperature from the SiC raw material to the SiC crystal rod includes: placing the pie crucible 100 in the insulation layer 210; The temperature field is constructed by using induction coil 220, heating resistor or microwave.

Specifically, the insulation layer 210 is a graphite felt insulation layer for wrapping the pie crucible 100.

In this embodiment, the induction coil 220 is arranged outside the insulation layer 210, and the induction coil 220 is used to construct a temperature field with a temperature gradient, in which the temperature from the SiC raw material 400 to the SiC crystal rod 300 gradually decreases.

The induction coil 220 may be a water-cooled induction coil 220.

It should be noted that the temperature field can also be constructed by means of resistance heating, in which case, the resistance is arranged inside the insulation layer 210.

Further, the heating temperature of SiC crystal rod 300 is 2000-2300° C. Heating temperature of SiC raw material 400 is 2200° C.-2600° C.

Specifically, the constructed temperature field can meet the temperature gradient of SiC crystal growth by PVT method. The heating temperature range of SiC crystal rod 300 is 2000° C.-2300° C., and the heating temperature range of SiC raw material 400 is 2200° C.-2600° C., so that the sublimated gaseous components Si, Si2C and SiC of SiC raw material 400 can be transported to the production interface of SiC crystal rod 300 for rapid diameter expansion growth.

Advantageously, the heating temperature of SiC crystal rod 300 is 2200° C.; Heating temperature of SiC raw material 400 is 2300° C.

Further, the crystal form of SiC crystal rod 300 is 4H or 6H crystal form.

Particularly, SiC crystal rod 300 may be a 20 mm thick 2-inch n-type 4H silicon carbide crystal round rod, a 20 mm thick 4-inch n-type 4H silicon carbide crystal round rod, a 20 mm thick 6-inch n-type 4H silicon carbide crystal round rod or a 20 mm thick 4-inch n-type 6H silicon carbide crystal round rod.

It should be noted that in this embodiment, the distance between the upper surface and the lower surface of the inner cavity 110 of the pie crucible 100 is 20 mm, so the length of the selected SiC crystal rod 300 is 20 mm. Of course, the size of the pie crucible 100 can also be other sizes to adapt to different sizes of SiC crystal rods 300.

Further, the SiC raw material 400 is an annular SiC block or a plurality of stacked SiC blocks, which are arranged in the inner cavity 110 of the pie crucible 100, taking the SiC crystal rod 300 as the central area, and there is a gap between the SiC raw material 400 and the SiC crystal rod 300, which is in a constructed temperature field with a temperature gradient, in which the temperature from the SiC raw material 400 to the SiC crystal rod 300 gradually decreases. The sublimated gas of SiC raw material 400 is transported towards SiC crystal rod 300 and finally deposited on the surface of SiC crystal rod 300, so that SiC crystal rod 300 grows laterally, and the diameter expanding efficiency of SiC crystal rod 300 is improved.

Specifically, the SiC raw material 400 may be an annular SiC block or a monolithic sintered material. Or a monolithic SiC polycrystalline ring; Or a plurality of SiC blocks stacked in the circumferential direction of the inner cavity 110.

The production process of the SiC crystal growth method provided by the disclosure is as follows:

At first, a 20 mm thick 2-inch n-type 4H silicon carbide crystal round bar and SiC raw material 400 are sequentially loaded into the pie crucible 100, wherein the 20 mm thick 2-inch n-type 4H silicon carbide crystal round bar is placed in the center of the inner cavity 110 of the pie crucible 100, and the SiC raw material 400 is placed in the inner cavity 110 in an annular area with the crystal round bar as the center.

Secondly, the whole crucible is put into a SiC single crystal growth furnace, evacuated to a pressure below 1×10<−5> mbar, filled with argon to control the pressure under 500 mbar, the water-cooled induction coil 220 is turned on to inductively heat the pie crucible 100, and at the same time, a mixed gas of 500 sccm argon and 5 sccm nitrogen is introduced through a vent pipe, and the temperature of the region where the SiC crystal rod 300 is located is 200 deg c, The raw material area where SiC raw material 400 is located has a temperature of 2300° C. SiC raw material 400 is heated and sublimated into SiC gas, which can be transported from raw material area to SiC crystal rod 300 in lower temperature area along the temperature gradient for deposition, so that sic crystal rod 300 grows bigger in lateral direction. after 10 days of growth, a 4-inch n-type 4H crystal with a thickness of 20 mm is obtained.

Finally, 30 qualified 4-inch N-type substrates are produced after the crystal slices after the diameter expansion.

It should be noted that by adopting the above method, a 4-inch N-type 4H silicon carbide crystal round rod with a thickness of 20 mm was placed in the center of the pie crucible 100, and after 10 days of growth, a 6-inch N-type 4H crystal with a thickness of 20 mm was obtained. After slicing the crystal, 30 qualified 6-inch N-type substrates were produced.

In the same way, by adopting the above method, a 6-inch N-type 4H silicon carbide crystal round rod with a thickness of 20 mm was placed in the center of the pie crucible 100, and after 10 days of growth, an 8-inch N-type 4H crystal with a thickness of 20 mm was obtained. After slicing the crystal, 30 qualified 8-inch N-type substrates were produced.

With the above method, a 20 mm thick 4-inch n-type 6H silicon carbide crystal round bar was placed in the center of the pie crucible 100, and after 10 days of growth, a 20 mm thick 6-inch n-type 6H crystal was obtained. After slicing the crystal, 30 qualified 6-inch N-type substrates were produced.

To sum up, the SiC crystal growth device provided by the present disclosure includes a pie crucible 100 and a heating mechanism; The pie crucible 100 comprises a hollow inner cavity 110, the center of the inner cavity 110 is provided with a SiC crystal rod 300, and both ends of the SiC crystal rod 300 are respectively abutted against the upper end face and the lower end face of the inner cavity 110; A SiC raw material 400 is arranged in the circumferential direction of the inner cavity 110, and a gap exists between the SiC raw material 400 and the SiC crystal rod 300; The heating mechanism is arranged outside the pie crucible 100, and is used for constructing a temperature field with gradually decreasing temperature from the SiC raw material 400 to the SiC crystal rod 300, so that the sublimated gas of the SiC raw material 400 can diffuse towards the SiC crystal rod 300 and be deposited on the side wall of the SiC crystal rod 300. A temperature field with gradually decreasing temperature is constructed between SiC crystal rod 300 and SiC raw material 400 by using a heating mechanism arranged in the circumferential direction of pie crucible 100, and the gas after heating and sublimation of SiC raw material 400 can be transmitted to SiC crystal rod 300 and deposited, so that SiC crystal rod 300 grows larger in the lateral direction, thereby growing small-sized SiC crystal rod 300 into large-sized crystal, without changing crucible diameter for many times, with high yield, short crystal diameter expanding time and high production efficiency.

The SiC crystal growth method provided by the present disclosure comprises the following steps: arranging a SiC crystal rod 300 at the center of an inner cavity 110 of a pie crucible 100; Setting SiC raw material 400 in the circumferential direction of inner cavity 110 with a gap between SiC raw material 400 and SiC crystal rod 300; A temperature field with gradually decreasing temperature from SiC raw material 400 to SiC crystal rod 300 is constructed. According to the SiC crystal growth method provided by the present disclosure, the lateral direction (radial direction) of the whole SiC crystal rod 300 is taken as the growth surface, and the diameter of the SiC crystal rod 300 is rapidly expanded by establishing a suitable growth environment, so that the time is short and the yield is high.

Finally, it should be noted that the above embodiments are only used to illustrate the technical scheme of the present disclosure, but not to limit it. Although the embodiments of the present disclosure has been described in detail with reference to the foregoing embodiments, those of ordinary skill in the art should understand that the technical solutions described in the foregoing embodiments can still be modified, or some or all of the technical features can be equivalently replaced; However, these modifications or substitutions do not make the essence of the corresponding technical solutions deviate from the scope of the technical solutions of each embodiment of the present disclosure.

What is claimed is:

1. A SiC crystal growth device comprising
a heating mechanism;
a pie crucible defied by a hollow inner cavity, a SiC crystal rod being disposable in a center of the hollow inner cavity, with two ends of the SiC crystal rod being respectively abutting an upper end face and a lower end face of the hollow inner cavity, a SiC raw material being arranged in a circumferential direction of the hollow inner cavity, and a gap being defined between the SiC raw material and the SiC crystal rod;
wherein the heating mechanism is arranged outside of the pie crucible and establishes a temperature field with gradually decreasing temperature from the SiC raw material to the SiC crystal row, sublimated gas of the SiC raw material being diffused towards the SiC crystal rod and deposited on a side wall of the SiC crystal rod.

2. The SiC crystal growth device of claim 1, wherein the heating mechanism comprises a heating body and a thermal insulation layer, the thermal insulation layer covering a circumference, a top, and a bottom of the pie crucible, the heating body being disposed outside the thermal insulation layer.

3. The SiC crystal growth device of claim 2, wherein the heating body is an induction coil.

4. The SiC crystal growth device according to claim 2, wherein the thermal insulation layer is a graphite soft felt insulation layer.

5. A SiC crystal growth method, comprising:
setting a SiC crystal rod at a center of an inner cavity of a pie crucible;
setting SiC raw materials in a circumferential direction of the inner cavity with a gap between the SiC raw materials and the SiC crystal rod;
establishing a temperature field with gradually decreasing temperature from the SiC raw material to the SiC crystal rod.

6. The SiC crystal growth method of claim 5, wherein the step of constructing the temperature field with gradually decreasing temperature from the SiC raw material to the SiC crystal rod includes:
placing the pie crucible in an insulating layer, the temperature field being established by a heating element selected from a group consisting of: induction coils, heating resistors and microwaves.

7. The SiC crystal growth method of claim 6, wherein a heating temperature of the SiC crystal rod is 2000-2300 degrees Celsius, and a heating temperature of the SiC raw material is 2200-2600 degrees Celsius.

8. The SiC crystal growth method of claim 7, wherein the heating temperature of the SiC crystal rod is 2200 degrees Celsius, and the heating temperature of SiC raw material is 2300 degrees Celsius.

9. The SiC crystal growth method of claim 5, wherein a crystal form of the SiC crystal rod is 4H or 6H crystal form.

10. The SiC crystal growth method of claim 5, wherein the SiC raw material is an annular SiC block.

11. The SiC crystal growth method of claim 5, wherein the SiC raw material is a plurality of stacked SiC blocks.
